(19) United States
(12) Patent Application Publication
(10) Pub. No.: US 2008/0116547 A1
(43) Pub. Date: May 22, 2008

(54) IC package keeping attachment level of leads on chip during molding process

(75) Inventor: Wen-Jeng Fan, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/600,919

(22) Filed: Nov. 17, 2006

(51) Int. Cl. H01L 23/495

(52) U.S. Cl. 257/676; 257/E23.014

(57) ABSTRACT

An IC package keeping the attachment level of leads on chip during molding process, mainly comprises a plurality of leads of a Lead-On-Chip (LOC) leadframe, a chip adhered under the leads, a plurality of bonding wires electrically connecting the chip to the leads, a plurality of first supporting columns disposed above some of the leads, a plurality of second supporting columns disposed under the some of the leads and a molding compound. The molding compound encapsulates the chip, the bonding wires, inner portions of the leads and sides of the first and second supporting columns. Therein, the first and second supporting columns are longitudinally corresponding to each other and adjacent the chip. The thickness including one of the first supporting columns, a corresponding one of the second supporting columns and one of the leads disposed corresponding to the selected first supporting column and the selected second supporting column is approximately as same as that of the molding compound. By means of the supporting columns in the package, it is able to prevent the problems of chip displacement during molding process and exposure of chip backside or the bonding wires.

### FIELD OF THE INVENTION

The present invention is relating to a LOC (Lead-On-Chip) semiconductor package, more particularly to an IC package keeping attachment level of leads on chip during molding process.

### BACKGROUND OF THE INVENTION

A LOC (Lead-On-Chip) leadframe is generally applied as a chip-carrier while fabricating a low cost semiconductor package, such as TSOP (Thin Small Outline Package). So called LOC leadframe is a leadframe without die pad, a chip is directly attached under the leads of the leadframe to shorten wire-bonding length. However, the leads could be weak to support chip under an unbalance mold flow, hence the leads may skew resulting in chip displacement, even an improper exposure of chip and bonding wires probably occur in further serious condition.

As showed in FIG. 1, a well-known LOC semiconductor package 100 mainly comprises a plurality of leads 110 of a LOC leadframe, a chip 120, a plurality of bonding wires 130 and a molding compound 140. Each lead 110 has a lower surface 111 and an upper surface 112. Active surface 121 of the chip 120 is attached to the lower surfaces 111 of the leads 110 via a plurality of two-sided adhesive tapes 150. Usually a plurality of bonding pads 122 are formed at a center area of the active surface 121 of the chip 120 and electrically connected to the leads 110 via the bonding wires 130. The molding compound 140 encapsulates the chip 120, the bonding wires 130 and inner portions of the leads 110. The chip 120 fixed by the leads 110 is sensitive to shift when molding. Regarding to the formation of the molding compound 140, some factors such as compound-injecting pressure, compound characteristic and flowing balance of compound will affect location of the chip 120 inside a mold cavity, such as chip inclination and chip displacement problems, particularly exposure of backside of the chip 120 or the bonding wires 130 from the molding compound 140 probably happening if the molding flow is unbalanced.

### SUMMARY OF THE INVENTION

In order to solve the problems mentioned above, a primary object of the present invention is to provide an IC package keeping attachment level of leads on chip during molding process, which can solve the problems of chip displacement during molding process and prevent exposure of chip or bonding wires from the molding compound from occurring.

One aspect of the present invention provides an IC package keeping attachment level of leads on chip during molding process, mainly comprising a plurality of leads of a LOC leadframe, a chip, a plurality of bonding wires, a plurality of first supporting columns, a plurality of second supporting columns and a molding compound. Active surface of the chip is attached to the lower surfaces of the leads. The bonding wires are applied to electrically connect the chip to the leads. The first supporting columns are disposed on the upper surfaces of some of the leads and the second supporting columns are disposed on the lower surfaces of the some of the leads. The molding compound encapsulates the chip, the bonding wires, inner portions of the leads and sides of the first and second supporting columns. The first and second supporting columns are longitudinally corresponding to each other and adjacent the chip. A thickness including one of the first supporting columns, a corresponding one of second supporting columns and one of the leads disposed corresponding to the selected first supporting column and the selected second supporting column is approximately as same as that of the molding compound. In another embodiment, the supporting columns may be optionally disposed on the lower or upper surfaces of some of the leads and are adjacent the chip to keep attachment level of the chip during molding process.

With regard to the package mentioned above, the first and second supporting columns may be rigid metal bars (RMB).

With regard to the package mentioned above, the first and second supporting columns may be harder than the leads in hardness.

With regard to the package mentioned above, the first supporting columns and the second supporting columns may have a plurality of outer ends exposed from the top surface and the bottom surface of the molding compound respectively.

With regard to the package mentioned above, the leads disposed with the first and second supporting columns may be dummy leads without function of electrical conduction.

With regard to the package mentioned above, the width of the leads disposed with the first and second supporting columns may be approximately from one to three times of that of the other leads.

With regard to the package mentioned above, the chip may have a plurality of bonding pads located at a center area of the active surface.

With regard to the package mentioned above, a longitudinal distance from the bottom surface of the molding compound to the lower surfaces of the leads may be approximately as same as that from the top surface of the molding compound to the upper surfaces of the leads.

With regard to the package mentioned above, the encapsulated inner portions of the leads are coplanar.

### DESCRIPTION OF THE DRAWINGS

FIG. 1 is a cross-sectional view of a well-known LOC semiconductor package.

FIG. 2 is a cross-sectional view of an IC package in accordance with the first embodiment of the present invention.

FIG. 3 is a plan view of the semiconductor package prior to encapsulation in accordance with the first embodiment of the present invention.

FIG. 4 is a cross-sectional view of another IC package in accordance with the second embodiment of the present invention.

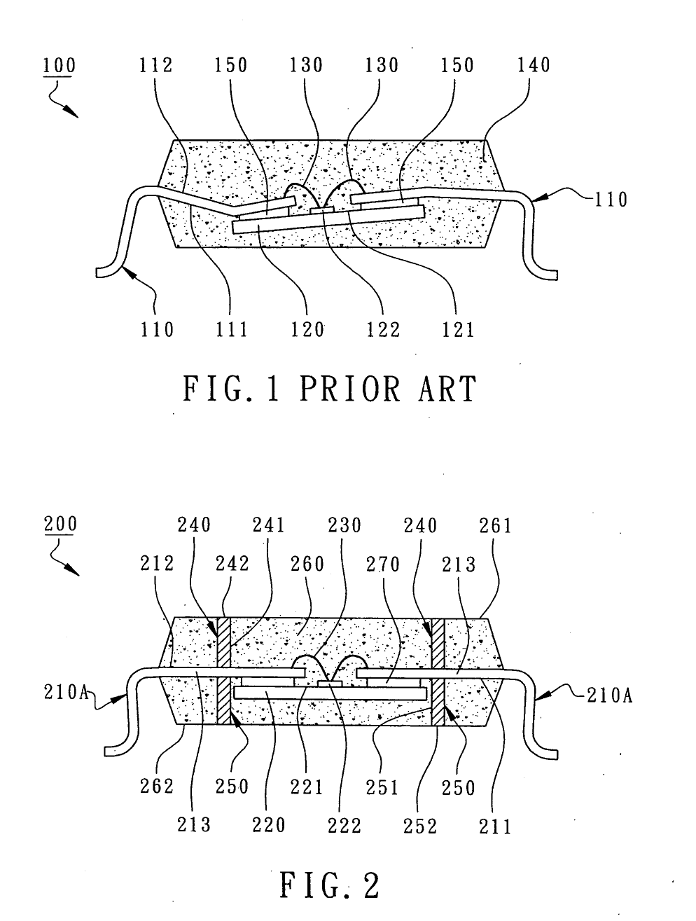

### DETAILED DESCRIPTION OF THE INVENTION

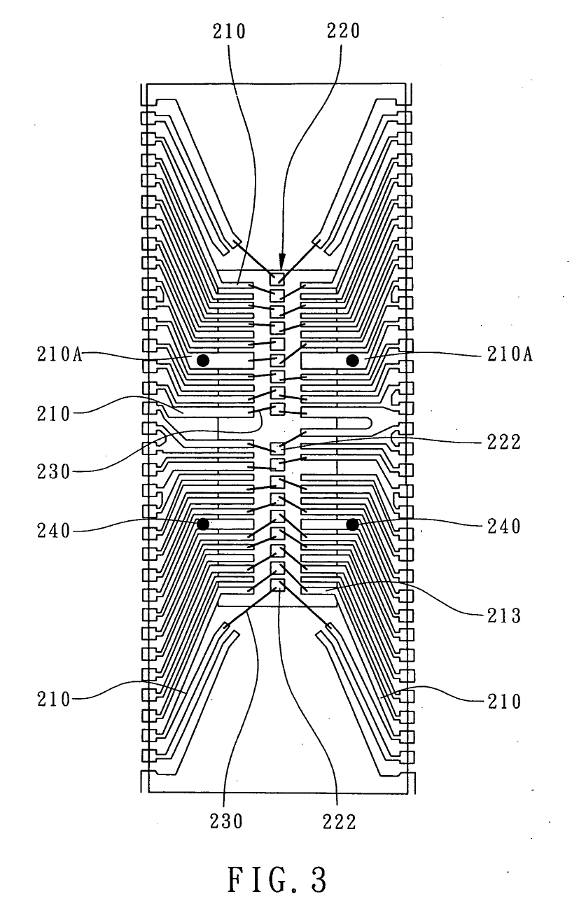

In the first embodiment of the present invention, FIG. 2 shows a cross-sectional view of an IC package keeping attachment level of leads on chip during molding process. FIG. 3 shows a plan view of the semiconductor package prior to encapsulation.

Referring to FIGS. 2 and 3, a semiconductor package 200 mainly comprises a plurality of leads of a LOC leadframe including 210, 210A, a chip 220, a plurality of bonding wires 230, a plurality of first supporting columns 240, a plurality of second supporting columns 250 and a molding compound 260. Referring now to FIG. 3, the leads not connected with the first supporting columns 240 are marked with reference number “210” and the leads connected to the first supporting columns 240 are marked with reference number “210A”. Referring to FIGS. 2 and 3, the LOC leadframe has no die pad, a plurality of chip-attaching tapes 270 or other chip-attaching materials are applied to adhere an active surface 221 of the chip 220 to the lower surfaces 211 of the leads 210. In this embodiment, the chip 220 has a plurality of bonding pads 222 located at a center area of the active surface 221 thereof for connection by the bonding wires 230.

The bonding wires 230 formed by wire-bonding technique are applied to electrically connect the bonding pads 222 of the chip 220 to the upper surfaces 212 of inner portions of the leads 210.

The first supporting columns 240 are disposed on the upper surfaces 212 of some 210A of the leads 210 and also the second supporting columns 250 are disposed on the lower surfaces 211 of the some 210A of the leads 210. Referring to FIG. 2, the first and second supporting columns 240, 250 are longitudinally corresponding to each other and adjacent the chip 220. Besides, a thickness including one of the first supporting columns 240, a corresponding one of the second supporting columns 250 and one 210A of the leads 210 disposed corresponding to the selected first supporting column 240 and the selected second supporting column 250 is approximately as same as that of the molding compound 260. During molding process, the first and second supporting columns 240, 250, can sustain upper and lower walls of molding cavity to obtain an excellent sustaining efficiency of leads in molding cavity. In this embodiment, outer ends 242 of the first supporting columns 240 and outer ends 252 of the second supporting columns 250 may be respectively exposed from the top surface 261 and the bottom surface 262 of the molding compound 260. Therein, so called “longitudinally corresponding to each other” means that each first supporting column 240 is formed on a vertical line aligned with the corresponding second supporting column 250. Moreover, the first and second supporting columns 240, 250 are adjacent the chip 220, that means the distance from the first supporting columns 240 or the second supporting columns 250 to sides of the chip 220 is shorter than that from the first supporting columns 240 or the second supporting columns 250 to the edges of the molding compound 260.

The molding compound 260 encapsulates the chip 220, the bonding wires 230, inner portions 213 of the leads 210 and the sides 241, 251 of the first and second supporting columns 240, 250. The molding compound 260 has a top surface 261 and a bottom surface 262. The outer ends 242 of the first supporting columns 240 may be exposed from the top surface 261 of the molding compound 260 and the outer ends 252 of the second supporting columns 250 may also be exposed from the bottom surface 262 of the molding compound 260. Preferably, the encapsulated inner portions 213 of all of the leads 210 and 210A are coplanar to lessen chip displacement and leadframe cost.

In this embodiment, the first and second supporting columns 240, 250 are rigid metal bars (RMB) formed with electroplating method and harder than the leads 210 in hardness. Also, a thickness from the bottom surface 262 of the molding compound 260 to the lower surfaces 211 of the leads 210 is approximately as same as that from the top surface 261 of the molding compound 260′ to the upper surfaces 212 of the leads 210, so that the first and second supporting columns 240, 250 can simultaneously be formed with electroplating method and particularly applied to TSOP66 for DDR device package of a same-size molding ratio.

Preferably, referring to FIG. 3, the foregoing leads 210A disposed with the first and second supporting columns 240, 250 are dummy leads without function of electrical conduction. For example, the package 200 may be applied to TSOP66 package of DDR SDRAM and according to JESD79E of JEDEC standards since a x8 component has NC dummy leads such as leads of 4th, 7th, 10th, 13th, 14th, 16th, 17th, 19th, 20th, 25th, 42nd, 43rd, 50th, 53rd, 54th, 57th and 60th, it can further pick dummy leads of proper location to serve as connections to the first and second supporting columns 240, 250. In this embodiment, the width of the leads 210A connected to the first and second supporting columns 240, 250 is approximately from one to three times of that of the other leads 210 not connected with the first and second supporting columns 240, 250 that typically have a width approximately between 90 μm and 160 μm.

Accordingly by means of sustaining by the first and second supporting columns 240, 250, the chip 220 won't displace or skew during forming the molding compound 260 and even the problem on improper exposure of chip backside and the bonding wires 20 can be solved.

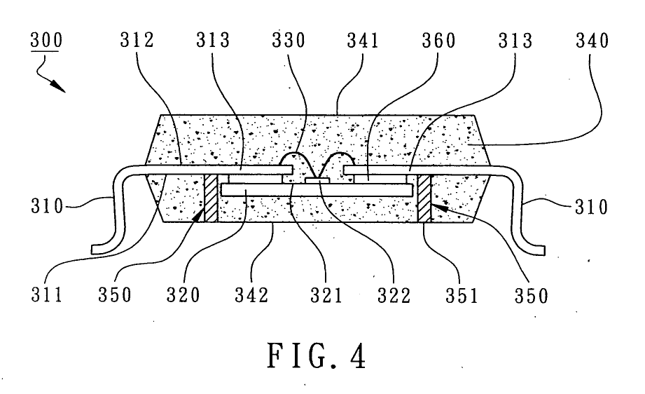

In the second embodiment of the present invention, another IC package keeping attachment level of leads on chip during molding process is disclosed. Referring to FIG. 4, a semiconductor package 300 mainly comprises a plurality of leads 310 of a LOC leadframe, a chip 320, a plurality of bonding wires 330, a molding compound 340 and a plurality of supporting columns 350. The active surface 321 of the chip 320 is attached to the lower surfaces 311 of the leads 310 with a plurality of chip-attaching tapes 360. The chip 320 has a plurality of bonding pads 322 located at a center area of the active surface 321 and electrically connected to the leads 310 by the bonding wires 330. The molding compound 340 encapsulates the chip 320, the bonding wires 330 and inner portions 313 of the leads 310. The supporting columns 350 are optionally disposed on the lower surfaces 311 or upper surfaces 312 of some of the leads 310 where displacement occurs frequently and adjacent the chip 320 to keep attachment level of chip 320 during molding process. Outer ends 351 of the supporting columns 350 are exposed from the bottom surface 342 or the top surface 341 respectively. In this embodiment, the supporting columns 350 are vertical to the leads 310. Particularly, in case of that a longitudinal distance from the bottom surface 342 of the molding compound 340 to a backside of the chip 320 is smaller than that from the top surface 341 of the molding compound 340 to the upper surfaces 312 of the leads 310. Accordingly, the molding flow is even unbalance, a mold flow pressure is downward. Moreover, the supporting columns 350 are disposed on the lower surfaces 311 of the some of the leads 310. The supporting columns 350 can further fulfill sustaining efficiency to prevent the chip 320 from displacing due to pressure difference of molding flow.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A semiconductor package comprising:
a plurality of leads of a LOC leadframe, wherein each lead has an upper surface and a lower surface;
a chip having an active surface attached to the lower surfaces of the leads;
a plurality of bonding wires electrically connecting the chip to the leads;
a plurality of first supporting columns disposed on the upper surfaces of some of the leads;
a plurality of second supporting columns disposed on the lower surfaces of the some of the leads; and
a molding compound encapsulating the chip, the bonding wires, a plurality of inner portions of the leads and a plurality of sides of the first and second supporting columns;
wherein the first and second supporting columns are longitudinally corresponding to each other and adjacent to the chip, wherein the thickness including one of the first supporting columns, a corresponding one of the second supporting columns and one of the leads disposed corresponding to the selected first supporting column and the selected second supporting column is approximately as same as that of the molding compound.

2. The semiconductor package in accordance with claim 1, wherein the first and second supporting columns are rigid metal bars (RMB).

3. The semiconductor package in accordance with claim 2, wherein the first and second supporting columns are harder than the leads in hardness.

4. The semiconductor package in accordance with claim 1, wherein the first supporting columns and the second supporting columns have a plurality of outer ends exposed from the top surface and the bottom surface of the molding compound respectively.

5. The semiconductor package in accordance with claim 1, wherein the leads disposed with the first and second supporting columns are dummy leads without function of electrical conduction.

6. The semiconductor package in accordance with claim 1, wherein the width of the leads disposed with the first and second supporting columns is approximately from one to three times of that of the other leads.

7. The semiconductor package in accordance with claim 1, wherein the chip has a plurality of bonding pads located at a center area of the active surface.

8. The semiconductor package in accordance with claim 4, wherein a longitudinal distance from the bottom surface of the molding compound to the lower surfaces of the leads is approximately as same as that from the top surface of the molding compound to the upper surfaces of the leads.

9. The semiconductor package in accordance with claim 1, wherein the encapsulated inner portions of the leads are coplanar.

10. A semiconductor package comprising:
a plurality of leads of a LOC leadframe, wherein each lead has an upper surface and a lower surface;
a chip having an active surface attached to the lower surfaces of the leads;
a plurality of bonding wires electrically connecting the chip to the leads;
a molding compound encapsulating the chip, the bonding wires and a plurality of inner portions of the leads; and
a plurality of supporting columns optionally disposed on the upper surfaces or the lower surfaces of some of the leads and adjacent the chip to keep the attachment level of the chip during molding.

11. The semiconductor package in accordance with claim 10, wherein the supporting columns are rigid metal bars (RMB).

12. The semiconductor package in accordance with claim 10, wherein the supporting columns are harder than the leads in hardness.

13. The semiconductor package in accordance with claim 10, wherein the supporting columns have a plurality of outer ends exposed from the molding compound.

14. The semiconductor package in accordance with claim 10, wherein the leads disposed with the supporting columns are dummy leads without function of electrical conduction.

15. The semiconductor package in accordance with claim 10, wherein the width of the leads disposed with the supporting columns is approximately from one to three times of that of the other leads.

16. The semiconductor package in accordance with claim 10, wherein the chip has a plurality of bonding pads located at a center area of the active surface.

17. The semiconductor package in accordance with claim 10, wherein the supporting columns are vertical to the leads.

18. The semiconductor package in accordance with claim 10, wherein a longitudinal distance from a bottom surface of the molding compound to a backside of the chip is smaller than that from a top surface of the molding compound to the upper surfaces of the leads, wherein the supporting columns are disposed on the lower surfaces of the some of the leads.

19. The semiconductor package in accordance with claim 10, wherein the encapsulated inner portions of the leads are coplanar.
